(19) United States
(12) Patent Application Publication
(10) Pub. No.: US 2025/0328703 A1
(43) Pub. Date: Oct. 23, 2025

(54) METHOD FOR DESIGNING GEOMETRY OF SUPERSONIC FLYING OBJECT, NON-TRANSITORY COMPUTER-READABLE MEDIUM STORING PROGRAM THEREFOR AND DESIGN DEVICE THEREFOR

(71) Applicant: Yuki UTSUMI, Kiyosu-shi (JP)

(72) Inventor: Yuki UTSUMI, Kiyosu-shi (JP)

(21) Appl. No.: 18/988,897

(22) Filed: Dec. 20, 2024

(30) Foreign Application Priority Data
Apr. 23, 2024 (JP) 2024-069670

(51) Int. Cl. G06F 30/15

(52) U.S. Cl. CPC G06F 30/15

(57) ABSTRACT

To provide a method for designing the geometry of a supersonic flying object that takes the off-track boom into consideration with the theoretical basis. A method for designing a geometry of a supersonic flying object, the method includes: a sinogram creation step of creating a sinogram that is defined as a result of applying Radon transform on singularity distribution or physical quantity distribution representing the geometry of the supersonic flying object; and a geometry reconstruction step of reconstructing the geometry of the supersonic flying object from the sinogram. The sinogram may be defined by a function that satisfies Helgason-Ludwig consistency condition for a non-circular domain. The sinogram may be derived from physical quantities defined by a cylindrical coordinate system that is coaxial with the supersonic flying object.

### CROSS-REFERENCE TO RELATED APPLICATIONS

This patent specification is based on Japanese patent application, No. 2024-069670 filed on Apr. 23, 2024 in the Japan Patent Office, the entire contents of which are incorporated by reference herein.

Utsumi, Y., “Inverse Design of Low-Boom Supersonic Aircraft with Cylindrical Pressure Distribution,” Journal of Aircraft, published online 17 Dec. 2024, URL https://doi.org/10.2514/1.C038054, the entire contents of which are incorporated by reference herein.

### TECHNICAL FIELD

The present disclosure relates to a method for designing a geometry of a supersonic flying object, a non-transitory computer-readable medium storing a program for making a computer execute a process for designing a geometry of a supersonic flying object, and a design device for designing a geometry of a supersonic flying object.

### BACKGROUND OF THE INVENTION

Concorde showed that the profitable market exists for supersonic travel on prime business routes. However, the route options were severely limited because the sonic boom prevented it from flying supersonically over land. Thus, sonic boom reduction is one of the keys to commercially successful supersonic aircraft.

There have been numerous studies on low-boom design. For example, see Patent Literature 1, and Non-Patent Literature 1-5. The sonic boom is an acoustic phenomenon that affects people, animals, or structures such as buildings on the ground during supersonic flight.

There exist broadly two methods for a design method with sonic boom reduction, hereinafter called low-boom design method; direct optimization and inverse design. The direct optimization searches for aircraft geometry that minimizes a sonic boom metric. The inverse design searches for a low-boom target near-field pressure distribution or an equivalent area and then reconstructs a geometry or adjusts an existing geometry so that the resulting geometry realizes the target. Most recent studies utilize the latter approach and have further advanced low-boom designs. The near-field pressure distribution is expressed by a function called F-function. The equivalent area refers to the cross-sectional area of a rotational body, assuming that the physical quantities at a distance from an aircraft flying at supersonic speeds are created by the rotational body. The physical quantities at a distance from the aircraft due to lift or other factors can also be expressed using the equivalent area in the form of the cross-sectional area distribution of an equivalent rotational body.

Most of the studies had focused on the sonic boom directly under-track. It means that a target F-function is defined by two variables, distance from aircraft in direction directly below the aircraft and distance in aircraft longitudinal direction. However, it has been known that off-track boom could be louder than under-track. Hereinafter, sonic boom in off-track direction is called off-track boom.

Low-boom design methods to consider off-track boom were proposed in the past. Non-Patent Literature 1 extended F-function to three dimensions to enable evaluation of off-track boom. A low-boom design framework by Non-Patent Literature 2 incorporated the calculation of off-track boom. Non-Patent Literature 3 defined target equivalent area distribution for off-track in addition to under-track to minimize sonic boom for both off-track and under-track. Non-Patent Literature 4 considered off-track boom by imposing a constraint on the second derivative of equivalent area for off-track. Non-Patent Literature 5 considered off-track boom by blending additional equivalent area for both under-track and off-track Mach planes to tailor fuselage cross-section.

### PRIOR ART LITERATURES

### Patent Literatures

[Patent Literature 1] International Publication No. 2019/187828

### Non-Patent Literatures

[Non-Patent Literature 1] Plotkin, K. J., “Sonic Boom Shaping in Three Dimensions,” 15th AIAA/CEAS Aeroacoustics Conference (30th AIAA Aeroacoustics Conference), 2009. https://doi.org/10.2514/6.2009-3387
[Non-Patent Literature 2] Ordaz, I., and Li, W., “Integration of Off-Track Sonic Boom Analysis for Supersonic Aircraft Conceptual Design,” Journal of Aircraft, Vol. 51, No. 1, 2014, pp. 23-28. https://doi.org/10.2514/1.C031511
[Non-Patent Literature 3] Ordaz, I., Wintzer, M., and Rallabhandi, S. K., “Full-Carpet Design of a Low-Boom Demonstrator Concept,” 33rd AIAA Applied Aerodynamics Conference, 2015. https://doi.org/10.2514/6.2015-2261
[Non-Patent Literature 4] Ueno, A., Kanamori, M., and Makino, Y., “Robust Low-Boom Design Based on Near-Field Pressure Signature in Whole Boom Carpet,” Journal of Aircraft, Vol. 54, No. 3, 2017, pp. 918-925. https://doi.org/10.2514/1.C033972
[Non-Patent Literature 5] Ueno, A., and Makino, Y., “Robust Low-Boom Design in Primary Boom Carpet,” AIAA Scitech 2021 Forum, 2021. https://doi.org/10.2514/6.2021-1270

### SUMMARY OF THE INVENTION

Although the advances mentioned above in low-boom design brought about significant improvements, an issue remains to be resolved. Consideration of off-track does not have a theoretical basis, and there is no guarantee that the target can be achieved.

For example, Non-Patent Literature 3 achieved some improvement but the resulting waveform did not match the target completely. The reason may be that three-dimensional F-function cannot be defined arbitrarily and the target waveform may have been infeasible.

The present disclosure provides a method for designing a geometry of a supersonic flying object, a non-transitory computer-readable medium storing a program for making a computer execute a process for designing a geometry of a supersonic flying object, and a design device for designing a geometry of a supersonic flying object.

A method for designing a geometry of a supersonic flying object according to a first embodiment of the present disclosure includes:
a sinogram creation step of creating a sinogram that is defined as a result of applying Radon transform on singularity distribution or physical quantity distribution representing the geometry of the supersonic flying object; and
a geometry reconstruction step of reconstructing the geometry of the supersonic flying object from the sinogram.

A non-transitory computer-readable medium storing a program for making a computer execute a process for designing a geometry of a supersonic flying object according to the second embodiment of the present disclosure includes:
a sinogram creation step of creating a sinogram that is defined as a result of applying Radon transform on singularity distribution or physical quantity distribution representing the geometry of the supersonic flying object; and
a geometry reconstruction step of reconstructing the geometry of the supersonic flying object from the sinogram.

A design device for designing a geometry of a supersonic flying object according to the third embodiment of the present disclosure includes:
a sinogram creation unit of creating a sinogram that is defined as a result of applying Radon transform on singularity distribution or physical quantity distribution representing the geometry of the supersonic flying object; and
a geometry reconstruction unit of reconstructing the geometry of the supersonic flying object from the sinogram.

According to the first embodiment of the present disclosure, since a geometry is reconstructed from a sinogram, it is possible to design the geometry of the supersonic flying object taking the off-track boom into consideration. There is theoretical basis for the feasibility of the sinogram created in the sinogram creation step (see “2. Theoretical basis for the sinogram creation step S20” described later). Therefore, it is possible to provide a method for designing the geometry of a supersonic flying object that takes the off-track boom into consideration with the theoretical basis.

According to the second embodiment of the present disclosure, the same effects as those of the first embodiment can be obtained. Therefore, it is possible to provide a non-transitory computer-readable medium storing a program for making a computer execute a process for designing a geometry of a supersonic flying object that takes the off-track boom into consideration with the theoretical basis.

According to the third embodiment of the present disclosure, the same effects as those of the first embodiment can be obtained. Therefore, it is possible to provide a design device for designing a geometry of a supersonic flying object that takes the off-track boom into consideration with the theoretical basis.

### BRIEF DESCRIPTION OF DRAWINGS

FIG. 1 is a diagram showing a design method of a geometry of a supersonic flying object according to an embodiment of the present disclosure.

FIG. 2 is a diagram explaining a definition of coordinates and projection.

FIG. 3 is a diagram explaining a process for geometry reconstruction according to an embodiment of the present disclosure.

FIG. 4 is a plan view showing the outer appearance of a supersonic flying object according to an embodiment of the present disclosure.

FIG. 5 is a graph comparing projection of lift and projection of reconstructed two-dimensional distribution according to an embodiment of the present disclosure.

FIG. 6 is a graph showing optimized three-dimensional F-functions according to an embodiment of the present disclosure.

FIG. 7 is a graph showing calculated sonic boom ground signatures according to an embodiment of the present disclosure.

FIG. 8 is a graph showing calculated perceived loudness of sonic boom according to an embodiment of the present disclosure.

### DETAILED DESCRIPTION OF THE INVENTION

A method for designing a geometry of a supersonic flying object includes: a sinogram creation step of creating a sinogram that is defined as a result of applying Radon transform on singularity distribution or physical quantity distribution representing the geometry of the supersonic flying object; and a geometry reconstruction step of reconstructing the geometry of the supersonic flying object from the sinogram.

In the method of designing the geometry of the supersonic flying object, the sinogram may be defined by a function that satisfies the Helgason-Ludwig consistency condition for non-circular domain. Since the sinogram adequate for supersonic aerodynamics can be created in the sinogram creation step, the reconstruction of the geometry can be facilitated in the geometry reconstruction step.

In the method of designing the geometry of the supersonic flying object, the sinogram may be derived from a physical quantity defined by a cylindrical coordinate system that is coaxial with the supersonic flying object. This can facilitate the evaluation of the sonic boom.

In the method of designing the geometry of the supersonic flying object, the geometry reconstruction step may use the limited angle tomography to reconstruct the geometry from a partially missing sinogram. This allows for reliable reconstruction of the geometry from a sinogram defined over a limited range.

In the method of designing the geometry of the supersonic flying object, the geometry reconstruction step may use the method of projections onto convex sets as the limited angle tomography and the projections onto multiple conditions, including the sinogram, are repeated in sequence. This allows for more reliable reconstruction of the geometry from a sinogram defined over a limited range.

A non-transitory computer-readable medium storing a program for making a computer execute a process for designing a geometry of a supersonic flying object includes: a sinogram creation step of creating a sinogram that is defined as a result of applying Radon transform on singularity distribution or physical quantity distribution representing the geometry of the supersonic flying object; and a geometry reconstruction step of reconstructing the geometry of the supersonic flying object from the sinogram.

In the non-transitory computer-readable medium storing the program for making the computer execute the process for designing the geometry of the supersonic flying object, the sinogram may be defined by a function that satisfies the Helgason-Ludwig consistency condition for non-circular domain. Since a sinogram adequate for supersonic aerodynamics can be created in the sinogram creation step, the reconstruction of the geometry can be facilitated in the geometry reconstruction step.

In the non-transitory computer-readable medium storing the program for making the computer execute the process for designing the geometry of the supersonic flying object, the sinogram may be derived from a physical quantity defined by a cylindrical coordinate system that is coaxial with the supersonic flying object. This can facilitate the evaluation of the sonic boom.

In the non-transitory computer-readable medium storing the program for making the computer execute the process for designing the geometry of the supersonic flying object, the geometry reconstruction step may use the limited angle tomography to reconstruct the geometry from a partially missing sinogram. This allows for reliable reconstruction of the geometry from a sinogram defined over a limited range.

In the non-transitory computer-readable medium storing the program for making the computer execute the process for designing the geometry of the supersonic flying object, the geometry reconstruction step may use the method of projections onto convex sets as the limited angle tomography and the projections onto multiple conditions, including the sinogram, are repeated in sequence. This allows for more reliable reconstruction of the geometry from a sinogram defined over a limited range.

A design device for designing a geometry of a supersonic flying object includes: a sinogram creation unit for creating a sinogram that is defined as a result of applying Radon transform on singularity distribution or physical quantity distribution representing the geometry of the supersonic flying object; and a geometry reconstruction unit for reconstructing the geometry of the supersonic flying object from the sinogram.

In the design device for designing the geometry of the supersonic flying object, the sinogram may be defined by a function that satisfies the Helgason-Ludwig consistency condition for non-circular domain. Since a sinogram adequate for supersonic aerodynamics can be created in the sinogram creation unit, the reconstruction of the geometry can be facilitated in the geometry reconstruction unit.

In the design device for designing the geometry of the supersonic flying object, the sinogram may be derived from a physical quantity defined by a cylindrical coordinate system that is coaxial with the supersonic flying object. This can facilitate the evaluation of the sonic boom.

In the design device for designing the geometry of the supersonic flying object, the geometry reconstruction unit may use the limited angle tomography to reconstruct the geometry from a partially missing sinogram. This allows for reliable reconstruction of the geometry from a sinogram defined over a limited range.

In the design device for designing the geometry of the supersonic flying object, the geometry reconstruction unit may use the method of projections onto convex sets as the limited angle tomography and the projections onto multiple conditions, including the sinogram, are repeated in sequence. This allows for more reliable reconstruction of the geometry from a sinogram defined over a limited range.

### 1. Summary of Design Method for Geometry of Supersonic Flying Object

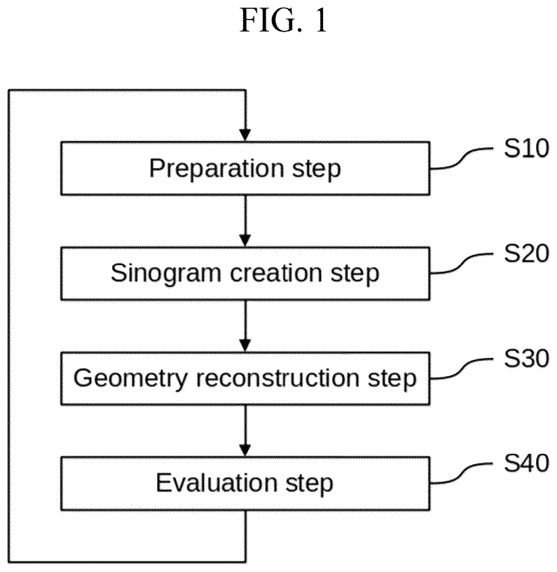

Hereinafter, embodiments of the present disclosure will be described with reference to FIGS. 1 through 8. As shown in FIG. 1, the method for designing a geometry of a supersonic flying object in this embodiment is broadly divided into four steps: the preparation step S10; the sinogram creation step S20; the geometry reconstruction step S30; and the evaluation step S40.

Among these four steps, the sinogram creation step S20 and the geometry reconstruction step S30 are programmed as the design program for making a computer execute a process for designing the geometry of the supersonic flying object. The design program for the geometry of the supersonic flying object, which includes the programmed sinogram creation step S20 and shape reconstruction step S30, is executed by a design device, a computer to be specific, for the geometry of the supersonic flying object. In other words, the design program for the geometry of the supersonic flying object is stored on a non-transitory computer-readable medium readable by the design device for the geometry of the supersonic flying object, and the design device reads and executes the design program from the non-transitory computer-readable medium.

In the design program, the sinogram creation step S20 is programmed as a sinogram creation step, and the geometry reconstruction step S30 is programmed as a geometry reconstruction step. In the design device, the sinogram creation step S20 is configured as a sinogram creation unit, and the geometry reconstruction step S30 is configured as a geometry reconstruction unit.

In the preparation step S10, calculations necessary for the preparation of the sinogram creation step S20 and the geometry reconstruction step S30 are performed. In the sinogram creation step S20, which follows the preparation step S10, a sinogram that meets predetermined conditions is created. The sinogram is defined as the result of a Radon transform of singularity distribution or physical quantity distribution representing the geometry of the supersonic flying object. In the geometry reconstruction step S30, the geometry is reconstructed based on the sinogram created in the sinogram creation step S20. In the evaluation step S40, the noise level of the sonic boom on the ground is calculated and evaluated based on the reconstruction results from the shape reconstruction step S30. Then, based on the evaluation results from the evaluation step S40, the preparation step S10, the sinogram creation step S20, the geometry reconstruction step S30, and the evaluation step S40 are repeated to optimize the geometry.

As described above, design methods in the past considering off-track booms lacked a theoretical basis. However, in this embodiment, by creating a sinogram that meets predetermined conditions in the sinogram creation step S20, it becomes possible to perform low-boom design with a theoretical basis. The theoretical basis for this will be explained below.

### 2. Theoretical Basis for Sinogram Creation Step S20

The theoretical basis for the design method considering off-track booms in this embodiment will be explained. First, the feasible cylindrical surface pressure distribution in linear supersonic flow is determined. Hereinafter, the function representing the cylindrical surface pressure distribution is referred to as the three-dimensional F-function. Once the feasible three-dimensional F-function in linear supersonic flow is formulated, it can be used to reconstruct the geometry.

When three dimensional F-function is available, it can be used to derive several kinds of valuable information, such as wave drag, volume, longitudinal center of the volume, lift, longitudinal center of lift, and sonic boom waveform on both under-track and off-track. If it is used in optimization, the supersonic flying object can be designed considering low-boom, low drag, and longitudinal trim without even considering geometry.

Three dimensionalities of the F-function can be expressed by decomposing it into multipoles. The multipoles are Fourier coefficients of the three dimensional F-function when expanded in circumferential direction. However, higher-order poles have fairly restrictive requirements and the multipoles cannot be defined arbitrarily. If the linear theory is used and nearly planar geometries are assumed, far-field pressure distribution can be calculated by integrating singularity on Mach cut. Mach cut is defined as an intersection of Mach plane and the plane on which a supersonic flying object exists. The singularity is a solution to the perturbation velocity potential equation. Differentiation of the perturbation velocity potential yields flow properties such as velocity, pressure, and etc. This integration, also called projection, is known as the Radon transform. It has been extensively studied in the fields of medical imaging (e.g., CT scan), astronomy, electron microscopy, and others, but not in the field of supersonic aerodynamics. The result of the Radon transform, which is called a sinogram, has to satisfy the Helgason-Ludwig consistency conditions. A function will be described that satisfies this condition and can be used for defining three dimensional F-function.

In linearized supersonic flow, assuming lateral symmetry, source strength and lifting element strength equivalent to source strength, in other words, singularities in linear supersonic theory, can be expressed as the equation F1.

$$\begin{matrix}[ equation F1 ] & \\ h ( x , y ) = f ( x , y ) + \frac{β {L}_{a} ( x , y )}{{M}_{∞} \sqrt{γ ρ {p}_{∞}}} cos θ & ( F1 )\end{matrix}$$

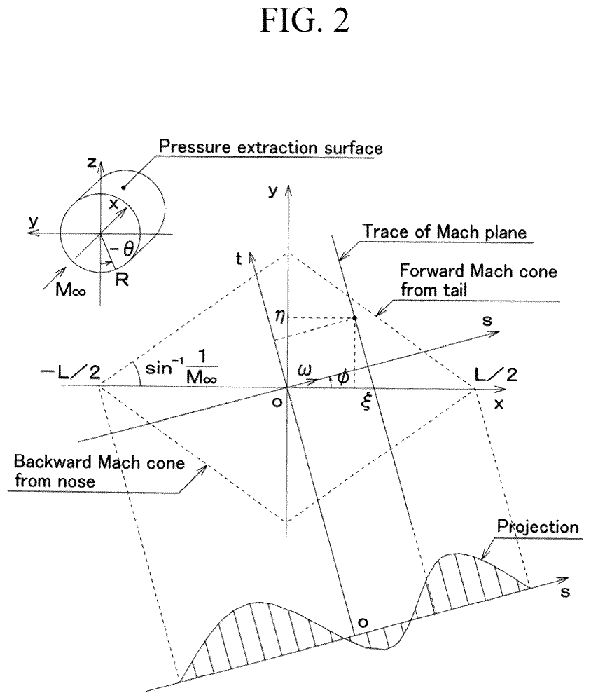

x, y, z are the axes in the Cartesian coordinate system shown in FIG. 2. h(x, y) is the source strength [m/s], or singularity in linear supersonic flow. f(x, y) is the source strength [m/s] due to thickness. β=√(M_{∞}²−1)·Lₐ(x, y) is the lift per unit area [N/m²]. M_{∞} is the freestream Mach number. γ is the specific heat. ρ is the freestream density [kg/m³]. ρ_{∞} is the freestream pressure [N/m²]. θ is the azimuth angle [rad].

FIG. 2 shows the definitions of coordinate system and projection used in this embodiment. In FIG. 2, o is the origin of Cartesian coordinate system. R is the radius of cylindrical surface [m]. s is the axis perpendicular to projection direction. t is the axis in the projection direction. φ is the projection angle [rad]. When a projection is created using the Mach cut of intersection between the Mach plane with the azimuth angle θ and z=0 plane, there exists a relationship tan φ=−β sin θ. ω is the vector with the x direction as cosφ and the γ direction as sin φ. ξ is the x coordinate [m] of the intersection point between the Mach cut and the x-axis. η is the γ coordinate [m]. L is the length of the supersonic flying object [m].

In the far-field, according to the known theorem, the magnitude of the perturbation velocity potential and its gradients at a fixed azimuth angle is invariant to a finite translation of singularities on a Mach plane. Under the assumption that the source and lifting elements are placed near the z=0 plane, a total source on a given Mach plane or Mach cut can be obtained by the equation F2.

$$\begin{matrix}[ equation F1 ] & \\ H ( ξ , θ ) = {\int }_{- ∞}^{∞} h ( ξ + β η sin θ , η ) d η & ( F2 )\end{matrix}$$

The perturbation velocity potential is given by the equation F3.

$$\begin{matrix}[ equation F3 ] & \\ {φ}_{p} ( τ , θ , R ) = \frac{- 1}{2 π \sqrt{2 β R}} {\int }_{- L / 2}^{τ} \frac{H ( ξ , θ )}{\sqrt{τ - ξ}} d ξ & ( F3 )\end{matrix}$$

Here, τ=x−βR.

The equations F1 through F3 relate the cylindrical pressure distribution to planar source and lift distributions. Three dimensional F-function and equivalent area are calculated by the equations F4 and F5.

$$\begin{matrix}[ equation F4 ] & \\ F ( τ , θ ) = \frac{1}{2 π} {\int }_{- L / 2}^{τ} \frac{\partial H ( ξ , θ ) / \partial ξ}{\sqrt{τ - ξ}} d ξ & ( F4 )\end{matrix}$$

$$\begin{matrix}[ equation F5 ] & \\ {A}_{c} ( τ , θ ) = {\int }_{- L / 2}^{τ} H ( ξ , θ ) d ξ & ( F5 )\end{matrix}$$

Since the three dimensional F-function can be calculated by H(ξ, θ), the problem of defining a feasible three dimensional F-function reduces to the problem of defining a feasible H (ξ, θ).

Changing variables of H (ξ, θ) by ξ cos ϕ=s and η=s sin ϕ+t cos ϕ, and redefining H(ξ, θ) as H_{c}(s, ω), the equation F2 can be expressed as the equation F6.

$$\begin{matrix}[ equation F6 ] & \\ H ( ξ , θ ) = {H}_{c} ( s , ω ) = cos φ {\int }_{- ∞}^{∞} h ( s cos φ - t sin φ , s sin φ + t cos φ ) dt & ( F6 )\end{matrix}$$

The integral in the equation F6 is called the Radon transform, and H_{c}(s, ω)/cos ϕ is called a sinogram. In other words, the Radon transform is an integration of two-dimensional function along a line. This line is moved in its perpendicular direction and is also rotated to provide a sinogram. In a more general case, the Radon transform can be applied to higher order dimensions, where the integration is conducted on a hyperplane. In medical imaging application, X-ray is irradiated to human body and X-ray transmittance is measured. Traversing the X-ray irradiation and doing this process for a range of angle provides a sinogram of human body. The sinogram can be calculated from the physical quantities defined in a cylindrical coordinate system that is coaxial with the supersonic flying object. Hereinafter, the sinogram H_{c} (s, ω)/cos ϕ is expressed as g(s, ω). The Radon transform is linear. Thus, h(x, y) in the equation F1 due to source and due to lift can be calculated separately.

Hereinafter, h(x, y) refers to its source or lift term. For the source term, substituting the equation F6 into the equation F5 applies integration to the equation F6. Changing the order of integration shows that integration of source term, i.e., thickness, instead of the source itself, can be used to derive the F-function. Thus, thickness distribution can be used instead of source, which enables the introduction of some constraints, such as minimum thickness, total volume, and others during optimization. The thickness distribution and lift distribution are the physical quantity distributions representing the geometry of the supersonic flying object that can be derived from the singularity distribution.

The sinogram g(s, ω) cannot be defined arbitrarily and must satisfy the Helgason-Ludwig consistency conditions. The Helgason-Ludwig consistency conditions are composed of two conditions. One condition, called projection-moment theorem, is that the equation F7 is a homogeneous polynomial of degree m with respect to the components of ω=(cos ϕ, sin ϕ). The other condition is the symmetry condition shown in the equation F8.

$$\begin{matrix}[ equation F7 ] & \\ {\int }_{- ∞}^{∞} {s}^{m} g ( s , ω ) ds & ( F7 )\end{matrix}$$

$$\begin{matrix}[ equation F8 ] & \\ g ( - s , - ω ) = g ( s , ω ) & ( F8 )\end{matrix}$$

Orthogonal functions that satisfy the Helgason-Ludwig consistency conditions have been proposed in the past in the fields of the medical imaging, astronomy, electron microscopy, outside of supersonic aerodynamics, as a method to extrapolate sinogram when it is not defined for some range of ϕ. These orthogonal functions could be used to construct a sinogram to calculate thickness or lift distribution. However, previously proposed orthogonal functions define sinogram in a circular domain while a diamond shape planform enclosed by backward and forward Mach cones from nose and tail, respectively, shown in FIG. 1 is adequate in supersonic aerodynamics.

In this embodiment, an orthogonal function g_{c}(r_{c}, ω) that satisfies the Helgason-Ludwig consistency conditions and spans from nose to tail is defined as the equation F9.

$$\begin{matrix}[ equation F9 ] & \\ {g}_{c} ( {r}_{c} , ω ) = \frac{1}{π} {\sum }_{k = 0}^{∞} {\sum }_{n = - ∞}^{∞} {b}_{k n} w ( {r}_{c} ) {P}_{k} ( {r}_{c} ) \frac{exp ( jn φ )}{\vert {cos}^{n + 1} φ \vert} & ( F9 )\end{matrix}$$

Here, r=s/(L/2), r=r_{c}|cos ϕ|, and bₖₙ=0 when |n|>k or k+|n| is an odd number. bₖₙ is the coefficient to define the sinogram. Pₖ(r_{c}) is a Gegenbauer polynomial of degree K with a weight function w(r_{c})=(1−r_{c}²)^{α-1/2}, α>1/2. j is the imaginary number. This function enables creation of sinogram. In other words, sinogram created by this function has a corresponding two-dimensional distribution. This function can be used by providing bₖₙ. This function satisfies the Helgason-Ludwig consistency conditions, as shown below.

For the projection-moment theorem, substituting the equation F9 into the equation F7 yield the equation F10.

$$\begin{matrix}[ equation F10 ] & \\ {\int }_{- ∞}^{∞} {g}_{c} ( {r}_{c} , ω ) {r}^{m} dr = \frac{1}{π} {\sum }_{k = 0}^{∞} {\sum }_{n = - ∞}^{∞} {b}_{k n} \frac{exp ( jn φ )}{\vert {cos}^{n + 1} φ \vert} {\vert cos φ \vert}^{m + 1} {\int }_{- 1}^{1} w ( {r}_{c} ) {P}_{k} ( {r}_{c} ) {r}_{c}^{m} {dr}_{c} & ( F10 )\end{matrix}$$

r_{c}^{m} in the equation F10 can be expanded by Gegenbauer polynomial as the equation F11.

$$\begin{matrix}[ equation F11 ] & \\ {r}_{c}^{m} = {\sum }_{q = 0}^{m} {d}_{q}^{m} {P}_{q} ( {r}_{c} ) & ( F11 )\end{matrix}$$

d_{q}^{m} is the coefficient for polynomial expansion when a power function is expanded by Gegenbauer polynomial.

Thus, the equation F10 can be expressed as the equation F12.

$$\begin{matrix}[ equation F12 ] & \\ {\int }_{- ∞}^{∞} {g}_{c} ( {r}_{c} , ω ) {r}^{m} dr = \frac{1}{π} {\sum }_{k = 0}^{∞} {\sum }_{n = - ∞}^{∞} {b}_{k n} \frac{exp ( jn φ )}{\vert {cos}^{n + 1} φ \vert} {\vert cos φ \vert}^{m + 1} {\sum }_{q = 0}^{m} {d}_{q}^{m} {\int }_{- 1}^{1} w ( {r}_{c} ) {P}_{k} ( {r}_{c} ) {P}_{q} ( {r}_{c} ) {dr}_{c} & ( F12 )\end{matrix}$$

Gegenbauer polynomial has an orthogonality relation shown in the equation F13.

$$\begin{matrix}[ equation F13 ] & \\ {\int }_{- 1}^{1} w ( {r}_{c} ) {P}_{k} ( {r}_{c} ) {P}_{q} ( {r}_{c} ) {dr}_{c} = {δ}_{kq} {c}_{k} & ( F13 )\end{matrix}$$

Here, δ_{kq} is the Kronecker delta, and cₖ=2π/k², which reduces the equation F12 to the equation F14.

$$\begin{matrix}[ equation F14 ] & \\ {\int }_{- ∞}^{∞} {g}_{c} ( {r}_{c} , ω ) {r}^{m} dr = \frac{1}{π} {\sum }_{k = 0}^{m} {\sum }_{n = - k}^{k} {b}_{k n} exp ( jn φ ) {cos}^{m - n} φ {d}_{k}^{m} {c}_{k} & ( F14 )\end{matrix}$$

Note that cos^{m-n} ϕ is always positive, and its absolute value sign can be removed. k+|n| is an even number by definition, and k+m is an even number because odd and even functions are expanded by odd and even polynomials respectively in the equation F11, and thus m−n is an even number.

Since exp (jnϕ) can be expressed by a homogeneous polynomial of degree n in cos ϕ and sin ϕ, the equation F14 is a homogeneous polynomial of degree m in the components of ω=(cos ϕ, sin ϕ). Thus, the equation F9 satisfies the projection-moment theorem of the Helgason-Ludwig consistency conditions.

For the symmetry condition, using the fact that w(r_{c}) is an even function, substituting the equation F9 into the left hand side of the equation F8 yields the equation F15.

$$\begin{matrix}[ equation F15 ] & \\ {g}_{c} ( - {r}_{c} , - ω ) = \frac{1}{π} {\sum }_{k = 0}^{∞} {\sum }_{n = - ∞}^{∞} {( - 1 )}^{n + k} {b}_{k n} w ( {r}_{c} ) {P}_{k} ( {r}_{c} ) \frac{exp ( jn φ )}{\vert {cos}^{n + 1} φ \vert} & ( F15 )\end{matrix}$$

Since k+|n| is an even number by definition, the equation F15 is identical to the equation F9, which shows that the symmetry condition in the equation F8 of the Helgason-Ludwig consistency conditions is satisfied.

In addition to the conditions above, the orthogonal function in the equation F9 should be zero at r_{c}=−1, 1 if the nose and tail are a pointed tip because the trace of the Mach plane at these locations has no length. Since α>1/2 by definition, w(r_{c})=(1−r_{c}²)^{α-1/2} is zero at r_{c}=−1, 1.

In this embodiment, the equation F9 is used aiming at creating a new geometry, but it can also be used to modify existing geometry. If the equation F9 is used for modifying existing geometry, the radon transform of the existing geometry is taken and expressed in the form of the equation F9. Then, some coefficients can be changed to define an updated feasible consistent target three dimensional F-function.

### 3. Process for Geometry Reconstruction Step S30

Once a feasible sinogram is defined, a corresponding two-dimensional distribution can be reconstructed. The sinogram for thickness provides two-dimensional thickness distribution. The sinogram for lift provides two-dimensional lift distribution. The lift distribution can be converted to camber distribution. A combination of thickness and camber defines geometry. The following explains the process of reconstructing the geometry based on the sinogram created in the sinogram creation step S20.

The Fourier transform of g(s, ω) is expressed by the equation F16.

$$\begin{matrix}[ equation F16 ] & \\ G ( {z}_{f} , ω ) = {\int }_{- ∞}^{∞} g ( s , ω ) exp ( - 2 π j {z}_{f} s ) ds & ( F16 )\end{matrix}$$

z_{f} is the radial coordinate in the frequency domain.

When sinogram g(s, ω) is given by H_{c}(s, ω)/cos ϕ, the equation F16 becomes the equations F17 and F18.

$$\begin{matrix}[ equation F17 ] & \\ G ( {z}_{f} , ω ) = {H}_{F} ( u , v ) & ( F17 )\end{matrix}$$

$$\begin{matrix}[ equation F18 ] & \\ {H}_{F} ( u , v ) = {\int }_{- ∞}^{∞} {\int }_{- ∞}^{∞} h ( x , y ) exp \{ - 2 π j ( ux + vy ) \} dx dy & ( F18 )\end{matrix}$$

Here, u=z_{f} cos ϕ, and v=z_{f} sin ϕ. The relations ξ cos ϕ=s, η=s sin ϕ+t cos ϕ, and the equation F19 based on FIG. 1 are used.

$$\begin{matrix}[ equation F19 ] & \\ ( \begin{matrix}s \\ t\end{matrix} ) = ( \begin{matrix}cos φ & sin φ \\ - sin φ & cos φ\end{matrix} ) ( \begin{matrix}x \\ y\end{matrix} ) & ( F19 )\end{matrix}$$

H_{F}(u, v) is a two dimensional Fourier transform of h(x, y). The equation F17 means that one dimensional Fourier transform of projection is identical to a slice of two dimensional Fourier transform of the two-dimensional distribution. It is called the Fourier slice theorem or projection-slice theorem. The equations F16 and F17 and changing variables s to r_{c} yield the equation F20.

$$\begin{matrix}[ equation F20 ] & \\ {H}_{F} ( u , v ) = \frac{L}{2} \vert cos φ \vert {\int }_{- ∞}^{∞} {g}_{c} ( {r}_{c} , ω ) exp ( - 2 π j {z}_{f} {r}_{c} \frac{L}{2} \vert cos φ \vert ) {dr}_{c} & ( F20 )\end{matrix}$$

Since g_{c}(r_{c}, ω) is given by the equation F9, H_{F}(u, v) can be calculated, and its inverse Fourier transform appears to yield h(x, y) according to the equation F18.

However, since the sinogram g(s, ω) is partially missing, specifically outside of the range −(π/2−μ)≤ϕ≤π/2−μ due to the relationship tan ϕ=−β sin θ, H_{F}(u, v) is only defined in the limited range −(π/2−μ)≤ϕ≤π/2−μ. It means that H_{F}(u, v) is not defined for the ranges π/2−μϕ<π/2 and −π/2≤ϕ<−(π/2−μ). Here, μ is the Mach angle [rad].

In other words, the Mach cut does not exist at all angles. When θ=0 degree, it is parallel to the y-axis, and when θ=90 or −90 degrees, it is at an angle of u to the x-axis. Outside of this range, the Mach cut does not geometrically exist.

Due to this deficiency in H_{F}(u, v), a two-dimensional inverse Fourier transform of H_{F}(u, v) cannot be taken to provide two-dimensional distribution h (x, y). This class of problems is known as limited angle tomography. It has been studied in fields outside of supersonic aerodynamics. There are three categories for the methods in solving this problem; iterative method, estimation method, and algebraic method.

The iterative method utilizes iterations between the object space and the projection space. A sinogram within the available angle is corrected using known constraints in each iteration to approach the solution. The estimation method utilizes the Helgason-Ludwig consistency conditions to estimate missing sinogram using available sinogram. The algebraic method solves a massive system of linear equations that results from a discretization of the Radon transform. Essentially, these are the methods for reconstruction from the sinogram whose originally missing domain is supplemented by available domain.

In this embodiment, an iterative method for reconstruction is applied using the projections onto convex sets, POCS, for the following reasons. It allows for the incorporation of constraints such as minimum thickness and the planform. POCS is a method that involves repeated projections onto multiple conditions, including the sinogram, in sequence.

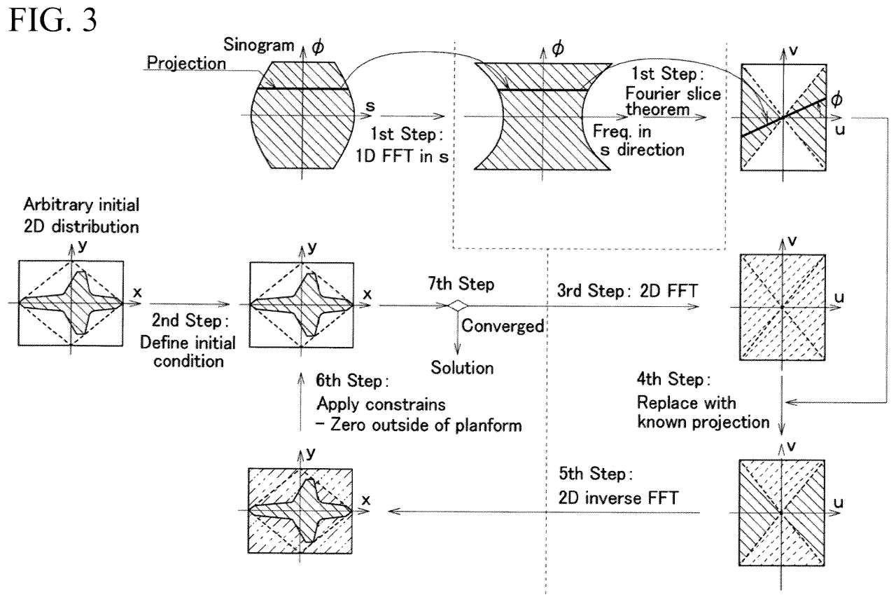

The reconstruction process is summarized in FIG. 3. The reconstruction process consists of the seven steps. The first step transforms the target sinogram into the frequency domain. One dimensional Fast Fourier Transform, FFT, is applied to the target sinogram at each projection angle. Using the Fourier slice theorem, one dimensional Fourier transform of projection that comprises sinogram is converted to a slice of two dimensional Fourier transform of the two-dimensional distribution at a corresponding projection angle. Doing this for all available projection angles creates the target sinogram in the frequency domain. The second step prepares an arbitrary two-dimensional distribution as an initial condition. In this embodiment, constant distribution within the planform is used. The third step takes the two dimensional FFT to convert the two dimensional distribution from spatial domain to frequency domain. The fourth step, in the frequency domain, replaces the values at ϕ within −(π/2−μ)≤ϕ≤π/2−μ where target is given. This step forces the current distribution in frequency domain to match the target sinogram. The fifth step takes the two-dimensional inverse FFT. The sixth step applies constraints in the spatial domain. In this embodiment, the value is set to zero outside the planform. Since a part of distribution in frequency domain is altered in the fourth step, value outside the planform deviates from zero. The loop shown in FIG. 3 is iterated. This is a process of POCS and it approaches to a point at which both the target sinogram in the frequency domain and constraints in the spatial domain are satisfied. The seventh step judges if convergence is achieved. With this method, a two-dimensional distribution that is consistent with the target sinogram is obtained.

The sinogram defined by the equation F9 is given in the polar coordinate system. Thus, a typical inverse FFT cannot define H_{F}(u, v) in the Cartesian coordinate system. In this embodiment, inverse FFTs are applied to the equation F9 for every angle, measured from x-axis, of grid points in the resulting spatial domain and only corresponding points on the Cartesian grid are retained to define H_{F}(u, v). A geometry can be reconstructed once h (x, y) is calculated separately for its thickness and lift contributions. The thickness distribution can be used as is. The lift distribution needs to be converted to a camber distribution using the known method. For each grid point, required lift and vertical component of airflow created by upstream lift elements yield required slope of the surface. Integration of the slope in streamwise direction gives camber distribution. A filter similar to a viscous vortex core is applied in this embodiment to avoid significant variations in spanwise camber.

### 4. Verification of Sinogram Creation Step and Geometry Reconstruction Step

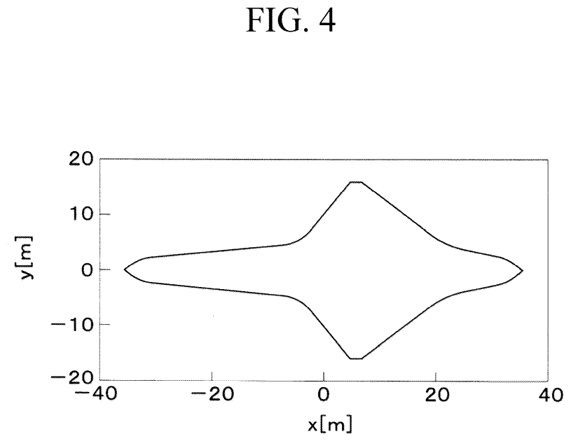

Sample target sinogram of lift is defined using the equation F9 to confirm that a two-dimensional distribution can be reconstructed from the target and that its sinogram matches the target. For flight conditions, the Mach number is 1.6 in this embodiment. The planform is shown in FIG. 4 in this embodiment. bₖₙ up to n=11 is used to define the sinogram of lift distribution in this embodiment, a for the weight of the Gegenbauer polynomial is set to 1.5 in this embodiment. 128×128 grid is used to define the two-dimensional distribution in this embodiment. The number of iterations is set to 1,000 in this embodiment.

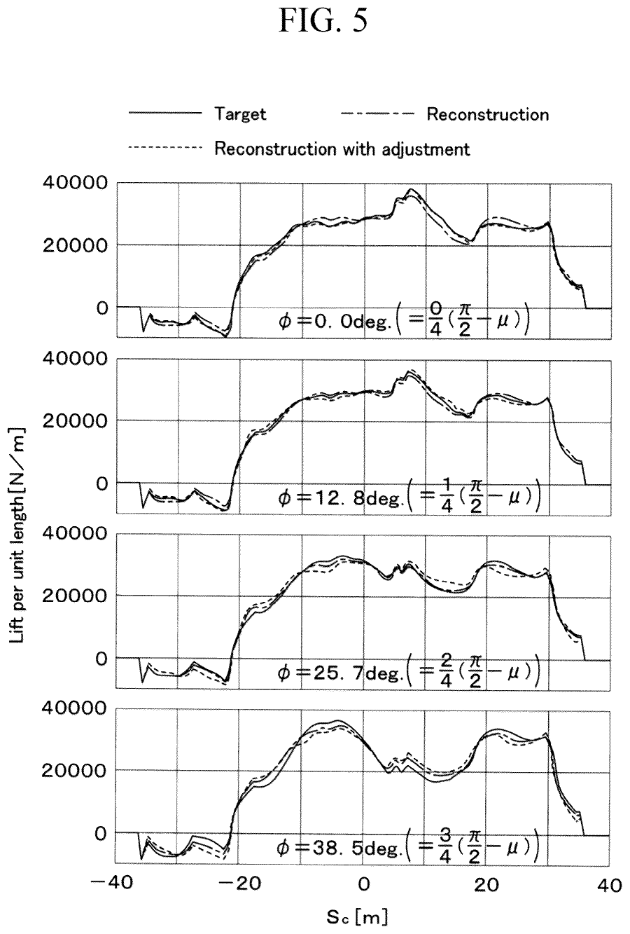

The target projections and the actual lift projections of the reconstructed two-dimensional distribution are shown in FIG. 5. The target and the actual agree well. For the slight discrepancy, when projections are desired to match exactly at a specific angle, it can be accomplished by adjustment where a difference of projection divided by the length of the trace is added to the two-dimensional distribution at that angle. However, it introduces slightly more discrepancies at other angles. For example, the adjustment to match the projections exactly at ϕ=0.0 deg. is shown by the dashed line in FIG. 5. Another workaround is to separate the planform into multiple parts to make larger the width and length ratio of each part. When this ratio is small, large variation in two dimensional distribution tends to be required, which may become unrealistic. The process shown here is applied to each part. If some parts are slender, equivalent areas can be directly used to reconstruct geometry. Since the process here is using linear theory, the results can be combined to create entire geometry.

### 5. Each Step of Design Method for Geometry of Supersonic Flying Object

As mentioned previously, the design method for geometry of supersonic flying object in this embodiment is divided into four steps; the preparation step S10, the sinogram creation step S20, the geometry reconstruction step S30, and the evaluation step S40. The following sections explain each of the steps; the preparation step S10, the sinogram creation step S20, the geometry reconstruction step S30, and the evaluation step S40.

### (1) Preparation Step S10

In the preparation step S10, age variable and ray-tube area are calculated. These are parameters for sonic boom propagation. The age variable is used to account for wave deformation due to nonlinear effects. The ray-tube area is used to account for wave attenuation during the propagation. Also, an equivalent area conversion step, an interpolation step, a lift distribution conversion step, and a definition step are performed. These steps facilitate definition of bₖₙ that are appropriate for sonic boom reduction. Instead of performing these steps, bₖₙ can also be defined directly depending on the purpose.

The equivalent area conversion step interpolates input under-track total F-function linearly, and converts it to the equivalent area. The interpolation step interpolates input under-track equivalent area due to volume by the non-uniform rational B-splines, or NURBS. The lift distribution conversion step subtracts equivalent area due to volume from total equivalent area to define equivalent area due to lift and convert it to lift distribution. The definition step defines sinogram of thickness and lift by the equation F9 using bₖₙ (n≥2) and subtracts them for under-track from the under-track thickness and lift projection, respectively, to define sinogram due to bₖₙ (n<2). The sum of the sinogram for bₖₙ (n≥2) and bₖₙ (n<2) is the sinogram to be used.

### (2) Sinogram Creation Step S20

The sinogram creation step S20 creates the target sinograms using the equation F9. The sinogram for lift is created from the coefficients bₖₙ for lift, and the sinogram for thickness is created from the coefficients bₖₙ for thickness. As mentioned previously, the sinogram is the result of applying Radon transform. Here, it means integration of two dimensional distribution of lift or thickness along Mach cut. Such two dimensional distributions do not exist yet, but the equation F9 can define the sinogram of such distributions before they exist.

### (3) Geometry Reconstruction Step S30

The geometry reconstruction step S30 applies previously described geometry reconstruction process to thickness and lift using the target sinogram created in the sinogram creation step S20.

### (4) Evaluation Step S40

The evaluation step S40 contains the vortex drag calculation step, the three dimensional F-function calculation step, the volume and the center of volume calculation step, the lift and the center of lift calculation step, the wave drag calculation step, and the ground sonic boom calculation step. Among the steps in the evaluation step S40, the three dimensional F-function calculation step has to be performed before the vortex drag calculation step and the ground sonic boom calculation step.

The vortex drag calculation step first calculates spanwise lift distribution. It is then used to calculate vortex drag using a known theory. The three dimensional F-function calculation step calculates sinogram from planar two dimensional distribution and calculates the three dimensional F-function using the equation F4. The volume and the center of volume calculation step calculates the volume and the center of volume from thickness distribution or zeroth order pole of equivalent area. The lift and the center of lift calculation step calculates lift and the center of lift from lift distribution or first order pole of equivalent area. The wave drag calculation step calculates the wave drag from the three dimensional F-function.

The ground sonic boom calculation step propagates F-function to ground to obtain ground sonic boom signature and calculates loudness. Near-field pressure distribution needs to be propagated to the ground with shock wave structure information available to evaluate the loudness of the sonic boom. The shock wave is a discontinuous rise of pressure but the rise time is not zero in reality. This pressure rise affects the loudness significantly. In this embodiment, it is accomplished by simplifying the Burgers equation's diffusion term and solving the equation by Cole-Hopf transformation.

The preparation step S10, the sinogram creation step S20, the geometry reconstruction step S30, and the evaluation step S40 are repeated for optimization. There are some points in the process to be noted. The center of volume is substituted for the center of gravity as an initial guess. The projection directly under-track is adjusted to match the target exactly. For evaluation, values calculated from two-dimensional distributions are used, although it is possible to use the sinogram to evaluate values except for vortex drag.

When the sinogram creation step S20 and the geometry reconstruction step S30 are programmed as the design program for the geometry of the supersonic flying object, the inputs for executing the design program include the Mach number, a grid for defining the two-dimensional distribution of the singularities or physical quantities representing the geometry of the supersonic flying object, the planform, the coefficients bₖₙ for lift and bₖₙ for thickness used to define the sinogram using the equation F9, and the coefficients a of the Gegenbauer polynomials respectively. As a result of executing the design program, the reconstructed lift distribution and thickness distribution are output.

### 6. Design Example

An example of applying the design method of geometry for supersonic flying object described previously is explained. The supersonic flying object in this example is supersonic aircraft. For flight conditions, the Mach number is 1.6, altitude is 50,000 ft, and lift is 1.317×10⁶ N. The diameter of fuselage is 3.0 meters. The sonic boom ground reflection factor is 1.9. The frequency for loudness calculation is 10 kHz. The planform shown in FIG. 4 is used. Coefficients bₖₙ up to n=11 define the sinogram of thickness and lift distribution, respectively. α for the weight of the Gegenbauer polynomial is set to 1.5. 128×128 grid is used to define the two-dimensional distribution. The number of iterations for the reconstruction is set to 1,000. A genetic algorithm is used for optimization. It is an algorithm to optimize objective functions using a method inspired by biological evolution.

Objective functions are minimization of the maximum perceived loudness of sonic boom at azimuth angle θ of 0, 10, 20, 30, 40 deg., minimization of a sum of wave drag and vortex drag, and minimization of the distance between centers of volume and lift. Under-track total F-function is defined by linear interpolation of 12 points, and under-track equivalent area due to volume is defined by NURBS with 12 control points. Including bₖₙ for lift and thickness, the total number of design variables is 85. 600 populations evolved for 800 generations. In the genetic algorithm, each design is represented by a set of the design variables. The designs are ranked by a method that uses the objective functions with adjustment to ensure diversity of the designs. The designs with high rank will be combined to create a next generation. Iterating this process will improve the objective functions.

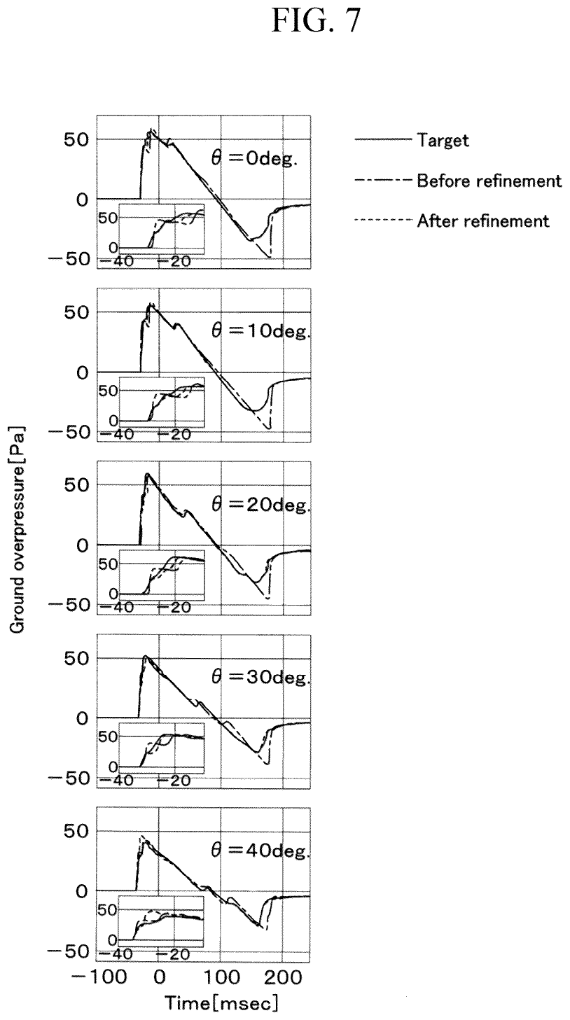

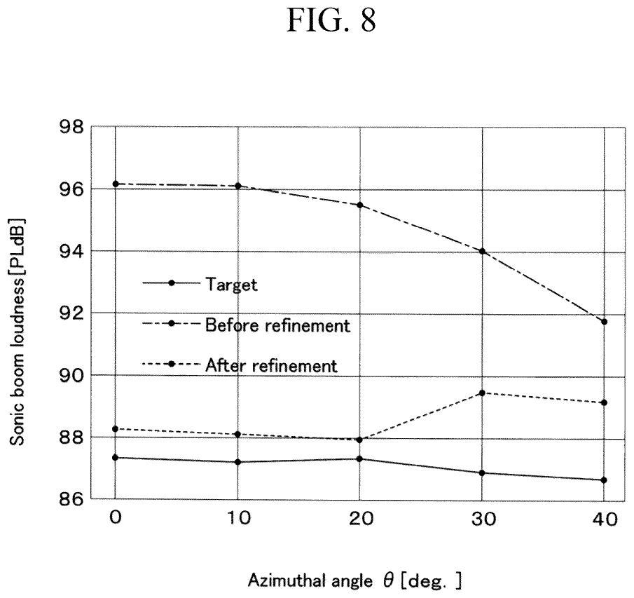

F-function in each azimuth angle θ is calculated by this lift and thickness distribution, and sonic boom ground signatures are calculated from the F-functions. The ground signatures may look like traditional N-waves, but they have a significantly longer rise time resulting in lower loudness than traditional N-waves. See dash-dot line in FIG. 7 described later. An N-wave refers to the waveform of a sonic boom as it propagates over a long distance, where the positive pressure part of the wave merges at the front and the negative pressure part merges at the rear, forming a waveform in the shape of the letter “N” composed of a leading shock wave, a trailing shock wave, and an expansion wave in between. The rise time of a traditional step sonic boom with 1 psf (47.88 Pa) shock is on the order of 1 ms whereas the ground signature from this optimization solution has a rise time on the order of 10 ms. This optimization achieved minimization of perceived loudness not only at the under-track but also at the off-track as shown by the solid line in FIG. 8 described later.

The geometry in this design example is obtained by linear theory. For the geometry to produce desired pressure disturbance in the real world, refinement with a nonlinear analysis is required. The geometry refinement process is described to refine the geometry to match the F-function obtained by a computational fluid dynamics, or CFD, which is a nonlinear analysis, to the target obtained by the process above. This process performs the steps in the following order: the geometry definition step; the CAD model creation step; the mesh creation step; the target F-function definition step; the inverse design step; and the post-processing step.

In the geometry definition step, the camber distribution is calculated from the lift distribution with the method mentioned previously. In the target F-function definition step, the near-field target F-function is defined. In other words, the target three dimensional F-function is propagated to a near-field cylindrical surface to account for nonlinear effects. This is required because CFD analysis provides three dimensional F-function that already includes nonlinear effects.

In the inverse design step, CFD analysis is conducted and inverse design to achieve the target three dimensional F-function is conducted. The objective function is to minimize the root sum squared of the difference between the actual three dimensional F-function obtained by CFD and target three dimensional F-functions within a specified azimuth angle. The gradient method is used as an optimization algorithm. Gradient of objective function with respect to the design variables is calculated and a new set of design variables is chosen in the direction of the steepest gradient. This process is iterated and, as a result, it improves the objective function. The multipole analysis is conducted to compare the three dimensional F-function with the target. When the multipole analysis and the near-field target F-function are utilized, F-functions by the linear theory and CFD can be compared with the same levels of the nonlinear and the circumferential flow effects. Geometry is deformed by free-form deformation, or FFD, with B-spline as an interpolation method. In this method, geometry to be deformed is enclosed by a mesh. When the vertices of the mesh are displaced, geometry inside is deformed as well using interpolation. In this embodiment, deformation of each vertex is a design variable for the optimization.

In the post-processing step, cylindrical pressure distribution is extracted from the CFD result. The multipole analysis is applied to resolve circumferential flow effects, and sonic boom propagation is conducted.

The example of applying the geometry refinement process is shown below. The design example shown above is used for the geometry definition step and the target F-function definition step. The calculation conditions are the same as the previous design example. A cylindrical surface with 1.5 times the aircraft length is used for near-field pressure extraction. Multipole of orders up to 13 are considered. FFD is defined by 10,062 vertices.

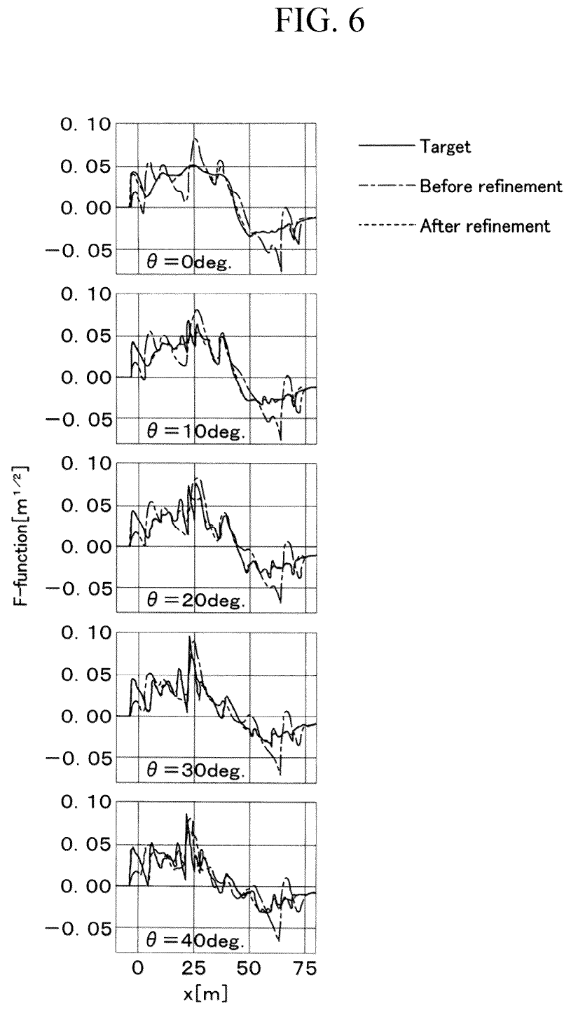

The optimization is terminated at 92 iterations. The F-function at each azimuth angle θ is shown in FIG. 6. The three dimensional F-function after refinement matches well with the target. Sonic boom ground signatures are shown in FIG. 7. The sonic boom ground signature after refinement matches well with the target.

The resulting loudness of the sonic boom is shown in FIG. 8. The loudness after refinement matches well with the target at the azimuth angles of 0, 10, and 20 deg and it is slightly higher at 30 and 40 deg. Nonetheless, it was improved toward the target for all azimuth angles compared to the one before geometry refinement. This result shows the validity of the proposed process.

In this embodiment, it was confirmed that the projection of the reconstructed geometry matches the target at multiple azimuth angles using the sample target. In the design example, a low-boom design was achieved at multiple azimuth angles in the first stage, and in the second stage, the design obtained in the first stage was refined using nonlinear CFD.

This embodiment answers long-standing unsolved problems, consistent three-dimensional F-function and geometry reconstruction. In other words, this embodiment provides a method for designing the geometry of a supersonic flying object that takes into account off-track booms with the theoretical basis.

The present disclosure is not limited to the embodiments above and can be applied to various embodiments as long as it does not depart from its gist.

For example, in the sinogram creation step S20 of the embodiments above, a sinogram satisfying the Helgason-Ludwig consistency condition is used, but the sinogram does not necessarily need to satisfy this condition. Even if the sinogram is not completely feasible, a sinogram that yields desired results when the result becomes closer to it can be used. For instance, while the sinogram in the embodiments above is not defined at ϕ=90 degrees, defining a sinogram where the spanwise distribution of lift (ϕ=90 degrees) is elliptical (i.e., minimizes vortex drag) can bring the spanwise lift distribution closer to the target and reduce vortex drag.

For example, in the geometry reconstruction step S30 of the embodiments above, the limited angle tomography, POCS to be specific, is used, but it is not limited to this. For instance, some optimization methods can be used to adjust the geometry so that the sinogram becomes closer to the target.

The supersonic flying object with geometry that is designed by at least one of the above-mentioned design method, design program, and design device effectively reduces off-track boom. They can also be used for purposes other than off-track boom such as low drag and longitudinal trim.

In the manufacturing method for manufacturing a supersonic flying object, if the supersonic flying object is manufactured with a geometry designed by at least one of the above-mentioned design method, design program, and design device, it is possible to manufacture a supersonic flying object with reduced off-track booms.

### Description of the Reference Numerals

S10 Preparation step
S20 Sinogram creation step (sinogram creation unit)
S30 Geometry reconstruction step (geometry reconstruction unit)
S40 Evaluation step

1. A method for designing a geometry of a supersonic flying object, the method comprising:
a sinogram creation step of creating a sinogram that is defined as a result of applying Radon transform on singularity distribution or physical quantity distribution representing the geometry of the supersonic flying object; and
a geometry reconstruction step of reconstructing the geometry of the supersonic flying object from the sinogram.

2. The method for designing the geometry of the supersonic flying object according to claim 1, wherein
in the sinogram creation step, the sinogram is defined by a function that satisfies Helgason-Ludwig consistency condition for a non-circular domain.

3. The method for designing the geometry of the supersonic flying object according to claim 1, wherein
in the sinogram creation step, the sinogram is derived from a physical quantity defined by a cylindrical coordinate system that is coaxial with the supersonic flying object.

4. The method for designing the geometry of the supersonic flying object according to claim 1, wherein
in the geometry reconstruction step, the geometry of supersonic flying object is reconstructed from a partially missing sinogram using a limited angle tomography.

5. The method for designing the geometry of the supersonic flying object according to claim 4, wherein
in the geometry reconstruction step, a method of projections onto convex sets is employed as the limited angle tomography, and
in the method of projections, the projections onto multiple conditions, including the sinogram, are repeated in sequence.

6. A non-transitory computer-readable medium storing a program for making a computer execute a process for designing a geometry of a supersonic flying object, the process comprising:
a sinogram creation step of creating a sinogram that is defined as a result of applying Radon transform on singularity distribution or physical quantity distribution representing the geometry of the supersonic flying object; and
a geometry reconstruction step of reconstructing the geometry of the supersonic flying object from the sinogram.

7. A design device for designing a geometry of a supersonic flying object, the design device comprising:
a sinogram creation unit for creating a sinogram that is defined as a result of applying Radon transform on singularity distribution or physical quantity distribution representing the geometry of the supersonic flying object; and
a geometry reconstruction unit for reconstructing the geometry of the supersonic flying object from the sinogram.
